(19) United States
(12) Patent Application Publication
(10) Pub. No.: US 2025/0372519 A1
(43) Pub. Date: Dec. 4, 2025

(54) MULTICHIP SEMICONDUCTOR BUILD WITH FLEXIBLE POWER AND SIGNAL DISTRIBUTION INTERCONNECTIONS

(71) Applicant: International Business Machines Corporation, Armonk, NY (US)

(72) Inventors: Manasa MEDIKONDA, ALBANY, NY (US); Tao Li, Slingerlands, NY (US); Ruilong Xie, Niskayuna, NY (US); Joshua M. Rubin, Albany, NY (US)

(21) Appl. No.: 18/678,679

(22) Filed: May 30, 2024

(51) Int. Cl. H01L 23/528; H01L 23/00; H01L 23/31; H01L 25/065

(52) U.S. Cl. CPC H01L 23/5286; H01L 23/3107; H01L 24/13; H01L 24/16; H01L 25/0652; H01L 24/14; H01L 2224/13147; H01L 2224/1403; H01L 2224/16145; H01L 2224/16225

(57) ABSTRACT

A semiconductor structure includes a first semiconductor chip having a surface with a plurality of conductive features thereon; a second semiconductor chip having a surface with a plurality of conductive features thereon; and a bridge chip coupling the first and second semiconductor chips through the pluralities of conductive features. The bridge chip includes a first surface facing the surfaces of the first and second chips with the conductive features thereon. The bridge chip has a second surface, a BEOL coupled to conductive features on the first surface that are in turn coupled to the pluralities of conductive features, an active device layer having a plurality of devices below the BEOL, a MOL layer in between the active device layer and the BEOL, and a backside power distribution network (BSPDN) below the active layer and coupled to devices on the active layer of the bridge chip.

### BACKGROUND

The present invention relates to the electrical, electronic, and semiconductor arts and, more particularly, to multichip semiconductor packaging.

A multichip semiconductor build requires a power distribution network to deliver power to each chip, with some chips requiring more power than other chips. Power can be distributed on a chip using the Back End of the Line (BEOL) and power can be passed through a chip using through silicon vias (TSV) and/or through insulator vias (TIV). Chips can be stacked on a plurality of levels and each level can have a plurality of chips requiring power distribution to fan out to many chips within a level and to many chips on each level without incurring an unacceptable voltage drop at the far end of the fan out.

### BRIEF SUMMARY

Principles of the invention provide techniques for multichip semiconductor build with flexible power and signal distribution interconnections. In one aspect, an exemplary semiconductor structure includes a first semiconductor chip having a surface with a plurality of conductive features thereon; a second semiconductor chip having a surface with a plurality of conductive features thereon; and a bridge chip coupling the first and second semiconductor chips through the pluralities of conductive features. The bridge chip includes a first surface facing the surfaces of the first and second chips with the conductive features thereon. The bridge chip has a second surface, and has a BEOL coupled to conductive features on the first surface that are in turn coupled to the pluralities of conductive features. The bridge chip further has an active device layer having a plurality of devices below the BEOL, a MOL layer in between the active device layer and the BEOL, and a backside power distribution network (BSPDN) below the active layer and coupled to devices on the active layer of the bridge chip.

In another aspect, another exemplary semiconductor structure includes an interposer having an upper surface and a plurality of metal pads thereon; and first and second semiconductor chips positioned above the interposer. Each the first and second semiconductor chips has a lower surface facing the upper surface of the interposer and each the lower surface of the first and second chips has a plurality of metal pads thereon. A bridge chip is positioned between the interposer and the first and second semiconductor chips; the bridge chip has an upper surface facing the lower surface of the first and second chips and the bridge chip has a lower surface facing the upper surface of the interposer. The bridge chip has a BEOL coupled to metal pads on the upper surface, an active device layer below the BEOL, a MOL layer in between the active device layer and the BEOL, and a backside power distribution network (BSPDN) below the active layer and coupled to metal pads on the lower surface. A first plurality of metal pillars connect from certain of the plurality of metal pads on the upper surface of the interposer to certain of the plurality of metal pads on the lower surface of the first and second semiconductor chips. A second plurality of metal pillars connect from certain of the plurality of metal pads on the upper surface of the interposer to certain of the metal pads on the lower surface of the bridge chip. A third plurality of metal pillars connect from certain metal pads from the upper surface of the bridge chip to certain of the plurality of metal pads on the lower surface of the first and second semiconductor chips. The structural configuration is such that power distribution to the first semiconductor chip, second semiconductor chip, and the bridge chip can be provided directly from the interposer via the first and second plurality metal pillars or via the bridge chip which in turn distributes power to the first and second semiconductor chips via the third plurality of metal pillars. Signal distribution to and from the first and second semiconductor chips can be provided directly via the first plurality of metal pillars or via the bridge chip which in turn distributes signals to the first and second semiconductor chips via the third plurality of metal pillars.

In still another aspect, still another exemplary semiconductor structure includes an upper level of first and second semiconductor chips stacked on top of a lower level of third and fourth semiconductor chips; and a bridge chip positioned between the lower level of the third and fourth semiconductor chips and the upper level of first and second semiconductor chips. The first and second semiconductor chips have a lower surface facing an upper surface of the bridge chip and an upper surface of the third and fourth semiconductor chips. The lower surface of the first and second semiconductor chips have a plurality of metal pads thereon, and each of the upper surface of the third and fourth semiconductor chips and the bridge chip have a plurality of metal pads thereon. The third and fourth semiconductor chips and the bridge chip have a lower surface and each the lower surface has a plurality of metal pads thereon. The bridge chip has a BEOL, an active device layer below the BEOL, and a backside power distribution network below the active device layer. Also included is an interposer having an upper surface facing the lower surface of the third and fourth semiconductor chips, a first plurality of metal pillars connecting from a certain plurality of metal pads on the upper surface of the interposer to certain of the plurality of metal pads on the lower surface of the third and fourth semiconductor chips, a second plurality of metal pillars connecting from a certain plurality of metal pads on the upper surface of the third chip to certain of the plurality of metal pads on the lower surface of the first semiconductor chip, a third plurality of metal pillars connecting from a certain plurality of metal pads on the upper surface of the fourth chip to certain of the plurality of metal pads on the lower surface of the second semiconductor chip, a fourth plurality of metal pillars connecting from a certain plurality of metal pads on the upper surface of the third chip to certain of the plurality of metal pads on the lower surface of the bridge chip, a fifth plurality of metal pillars connecting from a certain plurality of metal pads on the upper surface of the fourth chip to certain of the plurality of metal pads on the lower surface of the bridge chip, a sixth plurality of metal pillars connecting from a certain plurality of metal pads on the upper surface of the bridge chip to certain of the plurality of metal pads on the lower surface of the first semiconductor chip, and a seventh plurality of metal pillars connecting from a certain plurality of metal pads on the upper surface of the bridge chip to certain of the plurality of metal pads on the lower surface of the second semiconductor chip.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross-section view of a first embodiment of the invention.

FIG. 2 is an upside down cross-section view of a first interim structure in forming the embodiment of FIG. 1.

FIG. 3 is an upside down cross-section view of a second interim structure in forming the embodiment of FIG. 1.

FIG. 4 is a cross-section view of a second embodiment of the invention.

FIG. 5 is an upside down cross-section view of an interim structure in forming the embodiment of FIG. 4.

FIG. 6 is a cross-section view of a third embodiment of the invention.

FIG. 7 is an upside down cross-section view of an interim structure in forming the embodiment of FIG. 6.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure includes a first semiconductor chip having a surface with a plurality of conductive features thereon; a second semiconductor chip having a surface with a plurality of conductive features thereon; and a bridge chip coupling the first and second semiconductor chips through the pluralities of conductive features. The bridge chip includes a first surface facing the surfaces of the first and second chips with the conductive features thereon. The bridge chip has a second surface. The bridge chip has a BEOL coupled to conductive features on the first surface that are in turn coupled to the pluralities of conductive features, an active device layer having a plurality of devices below the BEOL, a MOL layer in between the active device layer and the BEOL, and a backside power distribution network (BSPDN) below the active layer and coupled to devices on the active layer of the bridge chip.

In some cases, the bridge coupling includes copper pillars.

In some cases, the bridge coupling includes hybrid bonds.

In some cases, the device layer includes memory devices.

In some embodiments, the backside power distribution network (BSPDN) is configured to provide power to the active device layer (for example, without the use of TSVs that connect to the BEOL on the frontside of the bridge and then to devices on the bridge).

In some such embodiments, the backside power distribution network (BSPDN) is further configured to provide power to one or more of the first and second semiconductor chips.

In some embodiments, the bridge chip is configured with a different operating voltage than at least one of the first and second semiconductor chips.

In some cases, the semiconductor structure further includes an interposer below the bridge chip, where the bridge chip is configured to pass signals between the first and second semiconductor chips and vertically to the interposer (e.g., through passive and/or active portions).

In another aspect, another exemplary semiconductor structure includes an interposer having an upper surface and a plurality of metal pads thereon; first and second semiconductor chips positioned above the interposer, each the first and second semiconductor chips having a lower surface facing the upper surface of the interposer and each the lower surface of the first and second chips have a plurality of metal pads thereon; and a bridge chip positioned between the interposer and the first and second semiconductor chips. The bridge chip has an upper surface facing the lower surface of the first and second chips and the bridge chip has a lower surface facing the upper surface of the interposer. The bridge chip has a BEOL coupled to metal pads on the upper surface, an active device layer below the BEOL, a MOL layer in between the active device layer and the BEOL, and a backside power distribution network (BSPDN) below the active layer and coupled to metal pads on the lower surface. A first plurality of metal pillars connect from certain of the plurality of metal pads on the upper surface of the interposer to certain of the plurality of metal pads on the lower surface of the first and second semiconductor chips, a second plurality of metal pillars connect from certain of the plurality of metal pads on the upper surface of the interposer to certain of the metal pads on the lower surface of the bridge chip, and a third plurality of metal pillars connect from certain metal pads from the upper surface of the bridge chip to certain of the plurality of metal pads on the lower surface of the first and second semiconductor chips. Power distribution to the first semiconductor chip, second semiconductor chip and bridge chip can be provided directly from the interposer via the first and second plurality metal pillars or via the bridge chip which in turn distributes power to the first and second semiconductor chips via the third plurality of metal pillars. Signal distribution to and from the first and second semiconductor chips can be provided directly via the first plurality of metal pillars or via the bridge chip which in turn distributes signals to the first and second semiconductor chips via the third plurality of metal pillars.

Some embodiments further include an underfill dielectric material through which the first, second and third plurality of metal pillars pass through.

In some embodiments, the bridge chip overlaps a portion of the lower surface of the first and second semiconductor chips.

In some cases, the first, second, and third metal pillars include copper bonded to metal pads.

In some cases, the bridge chip is bonded along one surface to copper pillars by hybrid bonds.

In some cases, the interposer includes a cavity for recessing the bridge chip a predetermined distance.

In still another aspect, still another exemplary semiconductor structure includes an upper level of first and second semiconductor chips stacked on top of a lower level of third and fourth semiconductor chips; and a bridge chip positioned between the lower level of the third and fourth semiconductor chips and the upper level of first and second semiconductor chips. The first and second semiconductor chips have a lower surface facing an upper surface of the bridge chip and an upper surface of the third and fourth semiconductor chips. The lower surface of the first and second semiconductor chips have a plurality of metal pads thereon, and each the upper surface of the third and fourth semiconductor chips and the bridge chip have a plurality of metal pads thereon. The third and fourth semiconductor chips and the bridge chip have a lower surface and each the lower surface have a plurality of metal pads thereon. The bridge chip has a BEOL, an active device layer below the BEOL, and a backside power distribution network below the active device layer. An interposer has an upper surface facing the lower surface of the third and fourth semiconductor chips. A first plurality of metal pillars connect from a certain plurality of metal pads on the upper surface of the interposer to certain of the plurality of metal pads on the lower surface of the third and fourth semiconductor chips. A second plurality of metal pillars connect from a certain plurality of metal pads on the upper surface of the third chip to certain of the plurality of metal pads on the lower surface of the first semiconductor chip. A third plurality of metal pillars connect from a certain plurality of metal pads on the upper surface of the fourth chip to certain of the plurality of metal pads on the lower surface of the second semiconductor chip. A fourth plurality of metal pillars connect from a certain plurality of metal pads on the upper surface of the third chip to certain of the plurality of metal pads on the lower surface of the bridge chip. A fifth plurality of metal pillars connect from a certain plurality of metal pads on the upper surface of the fourth chip to certain of the plurality of metal pads on the lower surface of the bridge chip. A sixth plurality of metal pillars connecting from a certain plurality of metal pads on the upper surface of the bridge chip to certain of the plurality of metal pads on the lower surface of the first semiconductor chip. A seventh plurality of metal pillars connect from a certain plurality of metal pads on the upper surface of the bridge chip to certain of the plurality of metal pads on the lower surface of the second semiconductor chip.

In some instances, the first through seventh metal pillars include copper bonded to metal pads.

In some such instances, the copper bonded to metal pads include hybrid bonds.

In some cases, the bridge chip is bonded on one surface to copper pillars by hybrid bonds. In some such cases, the one surface is the upper surface of the bridge chip.

In some instances, the third and fourth semiconductor chips are bonded on one surface to copper pillars by hybrid bonds.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:
including more functional units in a bridge chip, e.g. memory device
combining such a bridge chip with a back side power distribution network (BSPDN) process to facilitate signal communication between memory devices in the bridge and chiplets
combining such a bridge chip with a back side power distribution network (BSPDN) process to provide more power input from BSPDN to memory and/or to each chiplet through TSVs.

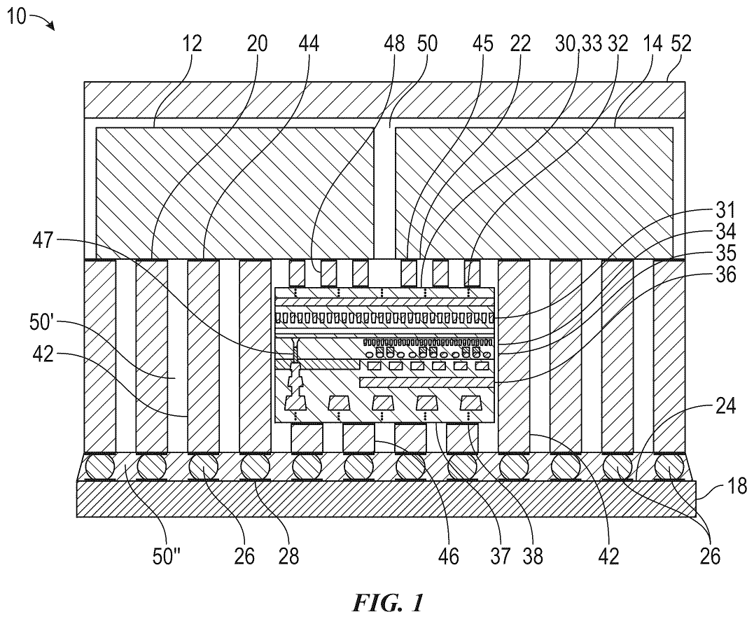

Aspects of the invention relate to multichip semiconductor structures including an overlapping semiconductor bridge chip having an added Backside Power Distribution Network (BSPDN) to facilitate power and signal distribution. Referring now to the drawing, FIG. 1 shows a cross section view of semiconductor structure 10 having semiconductor chips 12 and 14 positioned above an interposer 18. Semiconductor chips 12 and 14 have a surface 20 and 22 respectively facing a surface 24 of interposer 18. Interposer 18 can be a laminate, silicon substrate or a silicon chip. Interposer 18 has a plurality of metal pads 28 on upper surface 24. A bridge chip 30 is shown positioned below surfaces 20 and 22 of semiconductor chips 12 and 14 respectively and above surface 24 of interposer 18.

Bridge chip 30 has a back end of the line (BEOL 31) (i.e., BEOL wiring layer with vertical vias, horizontal metal lines, and dielectric layers) coupled to metal pads 32 on upper surface 33. BEOL insulation layers can be conventional dielectric layers such as TEOS or SiCN. BEOL 31 is coupled to a middle of the line (MOL) layer 34 below BEOL 31. The middle of the line layer 34 interconnects devices in active device layer 35 below MOL layer 34 to form circuit functions and connects active device layer 35 and circuit functions to BEOL 31. Note that middle of line (MOL) refers to the set of wafer processing steps (and corresponding structures/layers) used to create the structures that provide the local electrical connections between transistors; mainly gate contact formation; which occurs after front-end-of-line (FEOL) (transistors/devices) and before back-end-of-line (wiring) processes.

Active device layer 35 can include Si, SiGe, SiC or other semiconductor material. Active device layer 35 can have epitaxially grown source-drain regions, channels, gates, contacts, and other known device (e.g. field effect transistor (FET)) structures and materials. A backside power distribution network (BSPDN) 36 below (in at least some embodiments, directly below) active device layer 35 provides power to active device layer 35 and to BEOL 31. BEOL 31 is coupled to metal pads 38 on lower surface 37 of bridge chip 30. Bridge chip 30 can be smaller in area than semiconductor chips 12 and 14 and can overlap a portion of the lower surfaces 20 and 22 of semiconductor chips 12 and 14.

The area outside of the overlapped area of semiconductor chips 12 and 14 is available for contact by a plurality of metal pillars 42 from metal pads 44 and 45 on surfaces 20 and 22 respectively of semiconductor chips 12 and 14 to C4 metal bumps 26 on metal pads 28 on surface 24 of interposer 18. A plurality of metal pillars 46 extend from metal pads 38 on the lower surface 37 of bridge chip 30 to C4 solder bumps 26 on metal pads 28 on surface 24 of interposer 18. Metal pillars 46 can bring power to the backside power distribution network 36 on bridge chip 30. A plurality of metal pillars 48 are connected from metal pads 32 on surface 33 of bridge chip 30 to metal pads 44 and 45 respectively on surfaces 20 and 22 of semiconductor chips 12 and 14. Pillars 42 can have a pitch in the range from about 50 to 100 micrometers. Pillars 46 and 48 can have a pitch in the range from 10 to 50 micrometers. C4 (controlled collapsed chip connection) solder bumps 26 can have a pitch of about 100 micrometers. An underfill 50, 50′ and 50″ of organic or inorganic dielectric material physically holds the semiconductor chips 12 and 14, bridge chip 30, interposer 18 and pillars 42, 46 and 48, and package lid 52 in place. Underfill 50, 50′ and 50″ can be a dielectric material used in the BEOL 31.

Power distribution to semiconductor chip 12, semiconductor chip 14 and bridge chip 30 can be provided from interposer 18 via a plurality of metal pillars 42 and 46 or to bridge chip 30 via metal pillars 46 which in turn distributes power via backside power distribution network 36 to active device layer 35 and up through insulator vias (TIVs) 47 to a plurality of metal pads 32 to a plurality of metal pillars 48 to metal pads 44 and 45 on semiconductor chips 12 and 14. Signal distribution to and from semiconductor chips 12 and 14 can be provided via metal pillars 42 or through metal pillars 46 to bridge chip 30 which in turn distributes signals to and between semiconductor chips 12 and 14 via the plurality of metal pillars 48; for example, signals can flow vertically through bridge chip 30 from laminate or interposer 18 to bridge chip 30, and in some cases to semiconductor chips 12 and 14 above bridge chip 30, and signals can flow horizontally across bridge chip 30 between semiconductor chips 12 and 14.

Further, with respect to the metal pillars 42 and/or 46, it is possible that in some instances, there can be other lines/vias of (RDL) redistribution layers between semiconductor chips 12 and/or 14 and pillars 42 and/or 46. For example, one might want to form a layer of pads/vias to a bridge chip 30 and to adjacent (copper) metal pillars and then join chips 12 and/or 14 last. Furthermore, in one or more embodiments, the BSPDN 36 can directly power the devices in active device layer 35 on bridge chip 30 from the backside of the devices, so the TIVs 47 are employed to get power or signal to the frontside (BEOL-side) of bridge chip 30.

Metal pads 32, 38, 44 and 45 can have similar dimensions. Metal pads 32, 38, 44 and 45 can for example, be made of copper with a seeding liner such as Ta/TaN, Cu/Mn, or the like. Metal pads 32, 38, 44 and 45 can be circular in a top plan view and can range from 0.5 to 4 micrometers in diameter.

In the figures, like reference numerals are used for structures and functions corresponding to the description in an earlier figure.

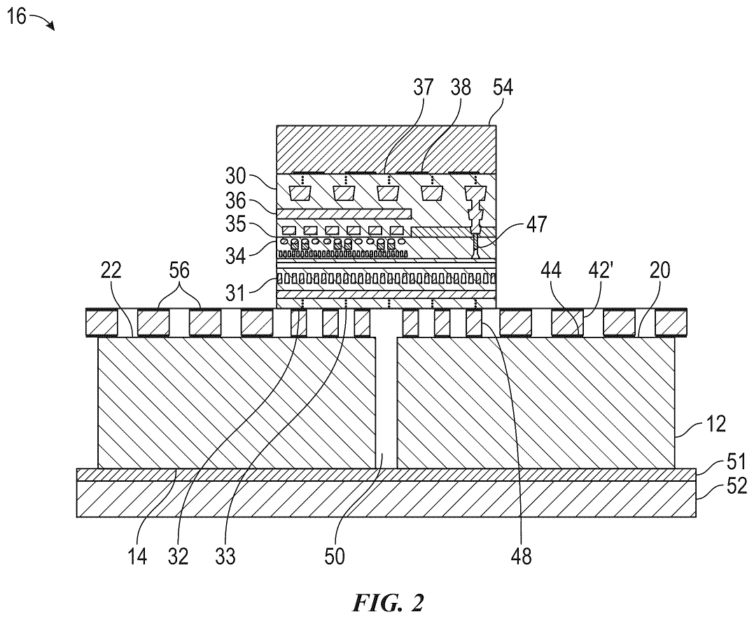

FIG. 2 shows an upside down cross section view of an interim structure 16 in forming semiconductor structure 10 shown in FIG. 1. FIG. 2 shows semiconductor chips 12 and 14 positioned on bonding pad 51 which is on carrier 52 for supporting semiconductor chips 12 and 14. Pillar segments 42′ and pillars 48 are formed, for example, by electroplating metal such as copper through a template or mask to a certain height. Next the template or mask is removed and the space between semiconductor chips 12 and 14 and pillar segments 42′ and pillars 48 is filled with underfill 50. Next, the upper surface of pillar segments 42′ and pillars 48 and underfill 50 is chemical mechanical polished (CMP) to form a smooth planar surface 56. Next, bridge chip 30 having metal pads 32 is positioned over respective pillars 48 and bonded by simultaneously heating and applying pressure to form hybrid bonds. Carrier 54 on surface 37 mechanically supports bridge chip 30 during positioning and hybrid bonding. Bridge chip 30 can be as thin as about 20 micrometers, for example.

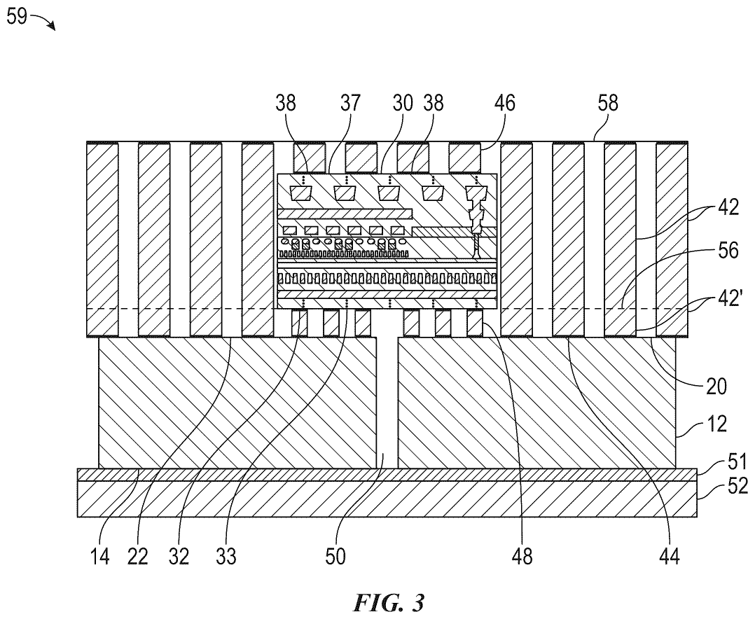

FIG. 3 shows an upside down cross section view of an interim structure 59 in forming semiconductor structure 10 shown in FIG. 1. FIG. 3 shows extension of pillar segments 42′ from surface 56 to surface 58 to form pillars 42 and the formation of pillars 46 from surface 37 to surface 58. Pillars, 42 and 46 can be formed, for example, by electroplating metal such as copper through a template or mask to a predetermined height. Next the template or mask is removed and underfilling is inserted into the spaces between pillars 42 and 46. The surface formed by excess underfill 50 and the tops of pillars 42 and 46 are polished by chemical mechanical polishing (CMP) to form a smooth planar surface 58 exposing the top surfaces of pillars 42 and 46 and underfill 50 at a predetermined height with respect to bonding pad 51. The spacing of pillars 46 and 48 can be smaller in the bridge chip region versus pillars 42 outside of the bridge chip region. Next, metal pads including, for example, NiAu and C4 solder bumps can be formed on the exposed end surfaces of pillars 42 and 46 shown in FIG. 1 as solder bump connections 26.

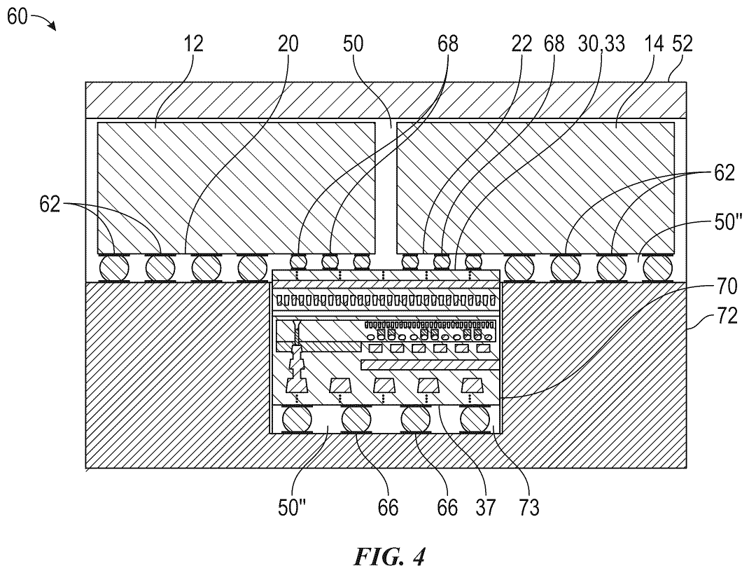

FIG. 4 shows a cross-section view of semiconductor structure 60 having C4 solder bump connections 62, 66 and 68 in place of metal pillars 42, 46 and 48 and hybrid bonds shown in FIG. 1 to make C4 solder bump connections and where bridge chip 30 is placed in a cavity or trench 70 formed in a laminate or silicon substrate 72. Cavity or trench 70 recesses bridge chip 30 by a predetermined amount to enable solder bump connections 66 at the bottom 73 of cavity or trench 70 and to enable solder bump connections 68 at surface 33 and solder bump connections 62 between substrate 72 and semiconductor chips 12 and 14. As shown in FIG. 4, micro solder bumps 68 can be used to connect from bridge chip 30 to semiconductor chips 12 and 14. An underfill 50 of dielectric material is used to hold in place laminate 72, semiconductor chips 12 and 14, bridge chip 30, solder bumps 62, 66 and 68 and lid 52. In place of solder bumps 62, 66 and 68, hybrid bonds can be formed in which case the dielectric material 50″ can be an inorganic material to withstand the bonding temperature. As will be appreciated by the skilled artisan, with micro bumps, underfill 50″ is typically needed. Furthermore, underfill 50″ can be different in the micro bump region vs. the solder bump region 62 vs. 66, depending on dimensions and required properties. Many variations will be apparent to the skilled artisan; for example, solder bumps 68 can be replaced by hybrid bonds or any other suitable high density bonding technique (Cu—Cu, etc.).

Semiconductor chips 12 and 14 can be joined to bridge chip 30 with a hybrid bond, which can in some instances require semiconductor chips 12 and 14 to be encapsulated in dielectric 50 and planarized before joining to bridge chip 30, and then solder bumps or balls 62 and 66 can be used to join the assembly to laminate 72 with a trench 70. Additionally, in some instances, bridge chip 30 is so thin that it may not require trench 70, and there may just be C4 solder bumps adjacent to bridge chip 30, with bridge chip 30 directly above laminate 72. In some instances, solder can be formed on laminate 72, since it will be hard to do on the assembled group of semiconductor chips 12, 14 and 30.

In hybrid bonding, a permanent bond combines a dielectric bond (e.g., SiOₓ) with embedded metal (e.g., Cu) to form interconnections. Two semiconductor builds are joined (e.g., two individual wafers that are built separately). They require a “pristine” surface (smooth and flat, possibly with some recesses), more so than traditional chemical-mechanical planarization (CMP). The two builds are purposely designed to align. The term “hybrid” refers to the presence of both copper and dielectric. A bond that uses dielectric alone is referred to as fusion bonding (oxide to oxide). Hybrid bonding uses metal to metal connections for the copper. The two builds are brought together and a small heat treatment/annealing process is carried out. The oxides bond together and the metals “anneal,” or almost melt, together, thus fusing the interface into a single bonded part (in some instances, seamlessly; i.e., the interface line disappears).

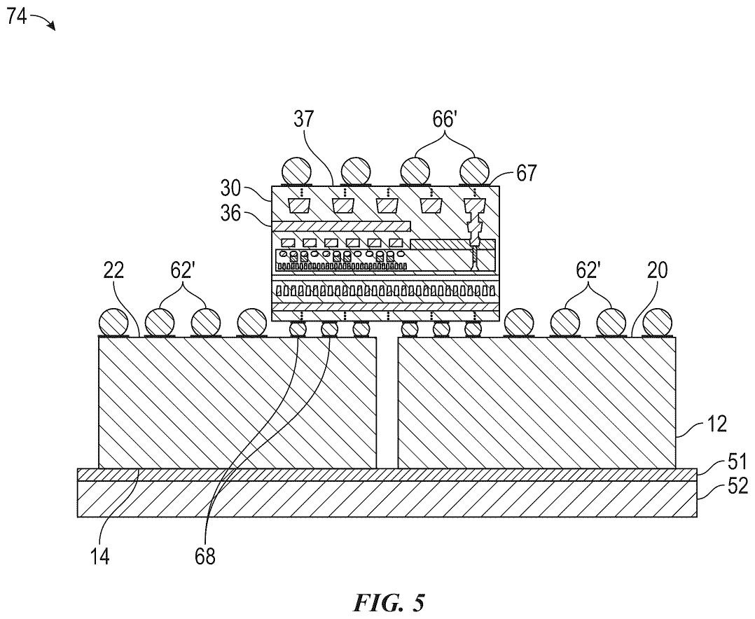

FIG. 5 shows an upside down cross section view of an interim structure 74 in forming semiconductor structure 60 shown in FIG. 4. FIG. 5 shows C4 solder bumps 62′ on semiconductor chips 12 and 14 and C4 solder bump connections 68 formed on bridge chip 30. Bridge chip 30 has C4 solder bumps 66′ on surface 37 connecting to respective metal pads 67 of Backside Power Distribution Network 36. Metal pad 67 can be finished with any suitable terminal metallization such as NiAu. Bridge chip 30 can be very thin such as 10 to 20 micrometers, due to an absence of semiconductor material such as silicon. A bridge chip carrier substrate (not shown) may be necessary to support bridge chip 30 prior to and during bonding to semiconductor chips 12 and 14. The bridge chip carrier substrate can be removed by laser de-bond if used.

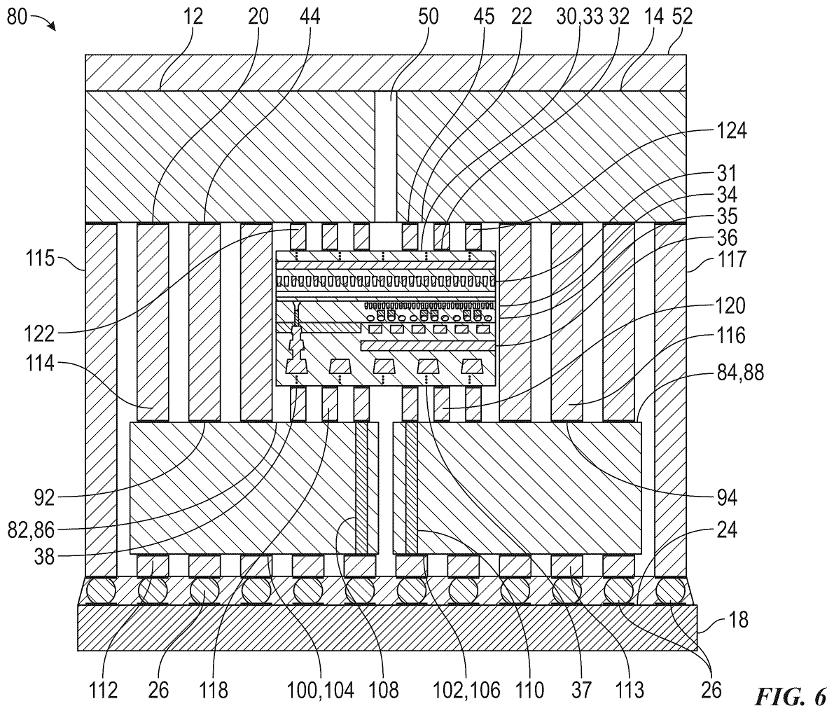

FIG. 6 shows a cross-section view of semiconductor structure 80 having a first level of semiconductor chips 12 and 14 on top of a second level of semiconductor chips 82 and 84. A bridge chip 30 is positioned between the second level of semiconductor chips 82 and 84 and the first level of semiconductor chips 12 and 14. Semiconductor chip 12 has a surface 20 facing surface 33 of bridge chip 30 and a portion of surface 86 of semiconductor chip 82. Surface 20 of semiconductor chip 12 has a plurality of metal pads 44 thereon. Surface 86 of semiconductor chip 82 has a plurality of metal pads 92 thereon, surface 33 of bridge chip 30 has a plurality of metal pads 32 thereon. Surface 100 of semiconductor chip 82 has a plurality of metal pads 104 thereon. Furthermore, surface 37 of bridge chip 30 has a plurality of metal pads 38 thereon.

Semiconductor chip 14 has a surface 22 facing surface 33 of bridge chip 30 and a portion of surface 88 of semiconductor chip 84. Surface 22 of semiconductor chip 14 has a plurality of metal pads 45 thereon. Surface 88 of semiconductor chip 84 has a plurality of metal pads 94 thereon. Surface 102 of semiconductor chip 84 has a plurality of metal pads 106 thereon.

Bridge chip 30 has a BEOL 31 coupled to metal pads 32 on upper surface 33 and to a middle of the line (MOL) layer 34 below BEOL 31. Middle of the line layer 34 interconnects devices in active device layer 35 below to form circuit functions and connects active device layer 35 to BEOL 31. A backside power distribution network (BSPDN) 36 is below active device layer 35. Backside power distribution network 36 below active device layer 35 is coupled to metal pads 38 on lower surface 37.

An interposer 18 is shown having a surface 24 facing the lower surfaces 100 and 102 of respective semiconductor chips 82 and 84. Semiconductor chips 82 and 84 have respective through silicon via (TSV) or through insulator via (TIV) 108 and 110 to provide high conductive paths through respective semiconductor chips 82 and 84 to pillars 118 and 120 to Backside Power Distribution Network 36 in bridge chip 30. Note that for illustrative simplicity and clarity, only a cross section is depicted; however, there can even be more than two chips on a given plane. For instance, three or four chips could be put together and a bridge chip 30 could be at the intersection of the chips so that it joins to more than two chips.

As shown in FIG. 6, except for C4 solder bumps on surface 24 of interposer 18, interconnections are made with metal pillars including copper which can be made in segments during manufacturing which also reduces the aspect ratio during plating. A first plurality of metal pillars 112 and 113 connect from a certain plurality of metal pads 26 on surface 24 of interposer 18 to certain of a plurality of metal pads 104 and 106 on respective surfaces 100 and 102 of semiconductor chips 82 and 84. Pillars 114 and 116 can be made, for example, of stacked vias or lines and vias, and the same is true for the “super tall” vias 115 and 117 depicted.

A second plurality of metal pillars 114 connect from a certain plurality of metal pads 92 on surface 86 of semiconductor chip 82 to certain of a plurality of metal pads 44 on surface 20 of semiconductor chip 12.

A third plurality of metal pillars 116 connect from a certain plurality of metal pads 94 on surface 88 of semiconductor chip 84 to certain of a plurality of metal pads 45 on surface 22 of semiconductor chip 14.

A fourth plurality of metal pillars 118 connect from a certain plurality of metal pads 92 on surface 86 of semiconductor chip 82 to certain of a plurality of metal pads 38 on surface 37 of bridge chip 30.

A fifth plurality of metal pillars 120 connect from a certain plurality of metal pads 94 on surface 88 of semiconductor chip 84 to certain of a plurality of metal pads 38 on surface 37 of bridge chip 30.

A sixth plurality of metal pillars 122 connect from a certain plurality of metal pads 32 on surface 33 of bridge chip 30 to certain of a plurality of metal pads 44 on surface 20 of semiconductor chip 12.

A seventh plurality of metal pillars 124 connect from a certain plurality of metal pads 32 on surface 33 of bridge chip 30 to certain of a plurality of metal pads 45 on surface 22 of semiconductor chip 14.

In FIG. 6, the lower semiconductor chips can communicate via the elevated bridge chip using the backside layers of the bridge chip and the upper chips can communicate via the elevated bridge chip via the frontside layers of the bridge chip. Furthermore, there can be communication amongst any of the semiconductor chips attached to the bridge chip.

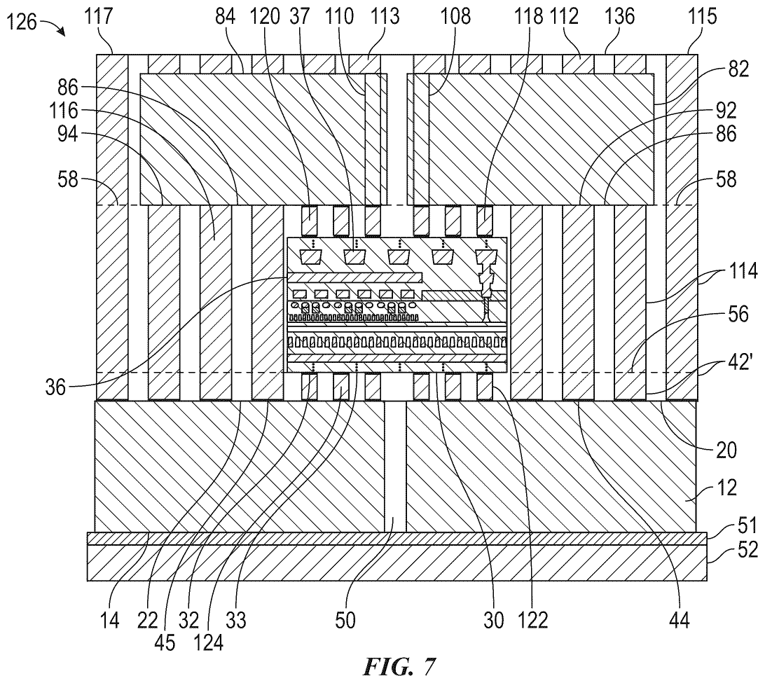

FIG. 7 shows an upside down cross section view of an interim structure 126 in forming semiconductor structure 80 shown in FIG. 6. FIG. 7 shows the first level of semiconductor chips 12 and 14 and the second level of semiconductor chips 82 and 84. A bridge chip 30 is shown inserted between the first and second level. In FIG. 7, copper pillars were formed extending from surfaces 20 and 22 of respective semiconductor chips 12 and 14 to a first height 56 suitable for positioning and hybrid bonding bridge chip 30 and then copper pillars are extended to a second height 58 to form pillars 114 and 116. Additional copper pillars 118 are formed from surface 37 of bridge chip 30 to second height 58.

Additional semiconductor chips 82 and 84 are placed on and bonded to the top surface ends of copper pillars 114, 116 and 118. Copper pillars 115 and 117 are extended to a third height and copper pillars 112 and 113 extend from semiconductor chips 82 and 84 to the third height. A template or mask (not shown) can be used to extend copper pillars to the third height, for example, by electroplating copper through a mask. The template or mask can be removed and an inorganic dielectric underfill 50 can be applied followed by chemical mechanical polishing to form a smooth planar surface 136 including underfill 50 of inorganic dielectric and the top surfaces of copper pillars 112, 113, 115 and 117.

Additional levels of semiconductor chips with bridge chips in between all or selected levels can be formed in addition to the stacked semiconductor chips shown in FIG. 6. While a cross-section view has been shown in the x and z direction in FIGS. 1-7, the cross section view can be taken from a portion of a three-dimensional array of semiconductor chips and bridge chips with each level having a plurality of semiconductor chips extending in the x and y direction and having a plurality of levels extending in the z direction.

There can be further stacking of semiconductor chips, such that there is one bridge chip, multiple chips above the bridge chip, then a second bridge chip, and multiple chips above the second bridge chip, and so on.

Furthermore, there can be a via/metal structure that is located between the lower chips 82 and 84, and is underneath bridge chip 30. This structure can provide power or signal directly to the second elevated bridge chip from the interposer/laminate 18 without needing to pass through the lower semiconductor chips 82 and/or 84.

Active device layer 35 in bridge chip 30 can include one or more memory arrays, such as SRAM, DRAM, or the like.

It is worth noting that in one or more embodiments, a BSPDN provides power to bridge chip devices (as opposed to TSVs that connect to BEOL on frontside of bridge and then to devices on bridge). One or more chips (or portions of chips) can obtain power distribution through the bridge chip via the BSPDN. The voltages supplied to the chips above the bridge may be the same or different supplies than those required for the bridge chip functionality. For instance, an I/O voltage supply may be needed on the chip 12, but a digital voltage supply may be needed on the bridge chip, etc.

In some instances, signals can pass between two or more chips connected to top side of bridge device. Signals can pass vertically through the bridge chip. The signal may pass from the chip(s) above the bridge through interconnects in the bridge to the substrate below the bridge. The signals may be going through only passive components of the bridge or they may be connected to active circuitry in the bridge.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on, useful in forming devices in the device layers. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first semiconductor chip having a surface with a plurality of conductive features thereon;
a second semiconductor chip having a surface with a plurality of conductive features thereon; and
a bridge chip coupling the first and second semiconductor chips through the pluralities of conductive features, the bridge chip including a first surface facing the surfaces of the first and second chips with the conductive features thereon, the bridge chip having a second surface, the bridge chip having a BEOL coupled to conductive features on the first surface that are in turn coupled to the pluralities of conductive features, an active device layer having a plurality of devices below the BEOL, a MOL layer in between the active device layer and the BEOL, and a backside power distribution network (BSPDN) below the active layer and coupled to devices on the active layer of the bridge chip.

2. The semiconductor structure of claim 1, wherein the bridge coupling includes copper pillars.

3. The semiconductor structure of claim 1, wherein the bridge coupling includes hybrid bonds.

4. The semiconductor structure of claim 1, wherein the device layer includes memory devices.

5. The semiconductor structure of claim 1, wherein the backside power distribution network (BSPDN) is configured to provide power to the active device layer.

6. The semiconductor structure of claim 5, wherein the backside power distribution network (BSPDN) is further configured to provide power to one or more of the first and second semiconductor chips.

7. The semiconductor structure of claim 1, wherein the bridge chip is configured with a different operating voltage than at least one of the first and second semiconductor chips.

8. The semiconductor structure of claim 1, further comprising an interposer below the bridge chip, wherein the bridge chip is configured to pass signals between the first and second semiconductor chips and vertically to the interposer.

9. A semiconductor structure comprising:
an interposer having an upper surface and a plurality of metal pads thereon,
first and second semiconductor chips positioned above the interposer, each the first and second semiconductor chips having a lower surface facing the upper surface of the interposer and each the lower surface of the first and second chips have a plurality of metal pads thereon, a bridge chip positioned between the interposer and the first and second semiconductor chips, the bridge chip having an upper surface facing the lower surface of the first and second chips and the bridge chip having a lower surface facing the upper surface of the interposer, the bridge chip having a BEOL coupled to metal pads on the upper surface, an active device layer below the BEOL, a MOL layer in between the active device layer and the BEOL, and a backside power distribution network (BSPDN) below the active layer and coupled to metal pads on the lower surface,
a first plurality of metal pillars connecting from certain of the plurality of metal pads on the upper surface of the interposer to certain of the plurality of metal pads on the lower surface of the first and second semiconductor chips,
a second plurality of metal pillars connecting from certain of the plurality of metal pads on the upper surface of the interposer to certain of the metal pads on the lower surface of the bridge chip, and
a third plurality of metal pillars connecting from certain metal pads from the upper surface of the bridge chip to certain of the plurality of metal pads on the lower surface of the first and second semiconductor chips,
whereby power distribution to the first semiconductor chip, second semiconductor chip and bridge chip can be provided directly from the interposer via the first and second plurality metal pillars or via the bridge chip which in turn distributes power to the first and second semiconductor chips via the third plurality of metal pillars and whereby signal distribution to and from the first and second semiconductor chips may be provided directly via the first plurality of metal pillars or via the bridge chip which in turn distributes signals to the first and second semiconductor chips via the third plurality of metal pillars.

10. The semiconductor structure of claim 9, further including an underfill dielectric material through which the first, second and third plurality of metal pillars pass through.

11. The semiconductor structure of claim 9, wherein the bridge chip overlaps a portion of the lower surface of the first and second semiconductor chips.

12. The semiconductor structure of claim 9, wherein the first, second, and third metal pillars comprise copper bonded to metal pads.

13. The semiconductor structure of claim 9, wherein the bridge chip is bonded along one surface to copper pillars by hybrid bonds.

14. The semiconductor structure of claim 9, wherein the interposer includes a cavity for recessing the bridge chip a predetermined distance.

15. A semiconductor structure comprising:
an upper level of first and second semiconductor chips stacked on top of a lower level of third and fourth semiconductor chips,
a bridge chip positioned between the lower level of the third and fourth semiconductor chips and the upper level of first and second semiconductor chips,
said first and second semiconductor chips having a lower surface facing an upper surface of the bridge chip and an upper surface of the third and fourth semiconductor chips,
said lower surface of the first and second semiconductor chips have a plurality of metal pads thereon, each the upper surface of the third and fourth semiconductor chips and the bridge chip have a plurality of metal pads thereon,
said third and fourth semiconductor chips and the bridge chip having a lower surface and each the lower surface having a plurality of metal pads thereon,
said bridge chip having a BEOL, an active device layer below the BEOL, and a backside power distribution network below the active device layer, and
an interposer having an upper surface facing the lower surface of the third and fourth semiconductor chips,
a first plurality of metal pillars connecting from a certain plurality of metal pads on the upper surface of the interposer to certain of the plurality of metal pads on the lower surface of the third and fourth semiconductor chips,
a second plurality of metal pillars connecting from a certain plurality of metal pads on the upper surface of the third chip to certain of the plurality of metal pads on the lower surface of the first semiconductor chip,
a third plurality of metal pillars connecting from a certain plurality of metal pads on the upper surface of the fourth chip to certain of the plurality of metal pads on the lower surface of the second semiconductor chip,
a fourth plurality of metal pillars connecting from a certain plurality of metal pads on the upper surface of the third chip to certain of the plurality of metal pads on the lower surface of the bridge chip,
a fifth plurality of metal pillars connecting from a certain plurality of metal pads on the upper surface of the fourth chip to certain of the plurality of metal pads on the lower surface of the bridge chip,
a sixth plurality of metal pillars connecting from a certain plurality of metal pads on the upper surface of the bridge chip to certain of the plurality of metal pads on the lower surface of the first semiconductor chip, and
a seventh plurality of metal pillars connecting from a certain plurality of metal pads on the upper surface of the bridge chip to certain of the plurality of metal pads on the lower surface of the second semiconductor chip.

16. The semiconductor structure of claim 15, wherein the first through seventh metal pillars comprise copper bonded to metal pads.

17. The semiconductor structure of claim 16, wherein the copper bonded to metal pads include hybrid bonds.

18. The semiconductor structure of claim 15, wherein the bridge chip is bonded on one surface to copper pillars by hybrid bonds.

19. The semiconductor structure of claim 18, wherein the one surface is the upper surface of the bridge chip.

20. The semiconductor structure of claim 15, wherein the third and fourth semiconductor chips are bonded on one surface to copper pillars by hybrid bonds.
